(19) United States
(12) Patent Application Publication
(10) Pub. No.: US 2026/0147953 A1
(43) Pub. Date: May 28, 2026

(54) Simulation System and Program

(71) Applicant: Softbank Group Corp., Tokyo (JP)

(72) Inventor: Masayoshi Son, Minato-ku, Tokyo (JP)

(21) Appl. No.: 19/122,058

(22) PCT Filed: Oct. 17, 2023
(86) PCT No.: PCT/JP2023/037597

§ 371 Date: Apr. 17, 2025

(30) Foreign Application Priority Data
Oct. 21, 2022 (JP) 2022-169079
Nov. 9, 2022 (JP) 2022-179649
Dec. 20, 2022 (JP) 2022-203354

(51) Int. Cl. G06F 30/17

(52) U.S. Cl. CPC G06F 30/17

(57) ABSTRACT

A simulation system includes: an acquisition unit that acquires sensor information detected by plural of sensors installed in an area in which a human worker moves and performs work; a generation unit that generates model data obtained by modeling a robot for replacing work of the human worker on the basis of the sensor information; and a display control unit that performs control to display the robot on the basis of the model data.

### TECHNICAL FIELD

The present disclosure relates to a simulation system and a program.

### BACKGROUND ART

Patent Literature 1 describes attitude control of a humanoid robot for automatically performing work in a production line of a factory.

### PRIOR ART DOCUMENT

### Patent Literature

Patent Literature 1: Japanese Patent Application Laid-Open (JP-A) No. 2019-093506

### SUMMARY OF INVENTION

### Solution to Problem

A simulation system according to a first aspect includes: an acquisition unit that acquires sensor information detected by a plurality of sensors installed in an area in which a human worker moves and performs work; a generation unit that generates model data obtained by modeling a robot for replacing work of the human worker on the basis of the sensor information; and a display control unit that performs control to display the robot on the basis of the model data.

According to a second aspect, in the first aspect, the generation unit updates the model data on the basis of the sensor information detected in real time.

According to a third aspect, in the first aspect or the second aspect, the simulation system further includes a selection unit that selects a robot for replacing the work of the human worker from among a plurality of types of robots having different specifications on the basis of the sensor information, in which the generation unit generates model data obtained by modeling the robot selected by the selection unit.

According to a fourth aspect, in the third aspect, the selection unit derives work information related to work of the human worker on the basis of the sensor information, and selects a robot on the basis of the derived work information.

According to a fifth aspect, in the fourth aspect, the work information includes at least one piece of information of a physique of the human worker, a weight of a work target object, a number of work target objects, a movement distance of the human worker, and a movement speed of the human worker.

According to a sixth aspect, in the third aspect, the specification includes at least one of a size of the robot, a weight of the robot, a maximum movement speed of the robot, a maximum weight of a conveyable object of the robot, and a maximum size of a conveyable object of the robot.

A program according to a seventh aspect causes a computer to function as an acquisition unit, a generation unit, and a display control unit of the simulation system in the first aspect.

A simulation system according to an eighth aspect includes: an acquisition unit that acquires sensor information detected by a plurality of sensors having a work space in which a human worker and a first robot each perform work accompanied by movement as a detection target; a generation unit that generates first model data obtained by modeling the work by the human worker and second model data obtained by modeling the work by the first robot on the basis of the sensor information acquired by the acquisition unit; and a control unit that performs a first simulation that simulates a situation in which the human worker and the first robot each perform the work in the work space on the basis of the first model data and the second model data generated by the generation unit.

According to the eighth aspect, it is possible to improve the accuracy of the first simulation that simulates a situation in which the human worker and the first robot perform work in a mixed manner.

According to a ninth aspect, in the eighth aspect, in a case in which a result of the first simulation satisfies a predetermined condition, the control unit performs processing of suggesting execution of at least one of a second simulation that simulates a situation in which a work speed of the first robot is changed with respect to the first simulation and a third simulation that simulates a situation in which at least a part of the human workers is replaced with a second robot with respect to the first simulation.

According to the ninth aspect, in a case in which the result of the first simulation satisfies a predetermined condition, for example, a condition that the work speed of the entire work space has not reached the target, it is possible for the user to recognize that there is a measure such as change of the work speed of the first robot and replacement of at least a part of the human workers with the second robot.

According to a tenth aspect, in the eighth aspect or the ninth aspect, in a case of performing a second simulation that simulates a situation in which the work speed of the first robot is changed with respect to the first simulation, the control unit sets the work speed of the first robot in the second simulation on the basis of the work speed of the individual human worker included in the first model data corresponding to the individual human worker.

According to the tenth aspect, the work speed of the first robot can be appropriately set on the basis of the work speed of the human worker in a case of performing the second simulation that simulates the situation in which the work speed of the first robot that performs work together with the human worker is changed.

According to an eleventh aspect, in the eighth aspect or the ninth aspect, in a case of performing a third simulation that simulates a situation in which at least a part of the human workers is replaced with a second robot with respect to the first simulation, the control unit selects the human worker to be replaced with the second robot in the third simulation on the basis of the work speed of the individual human worker included in the first model data corresponding to the individual human worker.

According to the eleventh aspect, in a case in which the third simulation simulating a situation in which at least a part of the human workers who works together with the first robot is replaced with the second robot is performed, the human worker to be replaced with the second robot can be appropriately selected on the basis of the work speed of the individual human worker.

According to a twelfth aspect, in the eighth aspect or the ninth aspect, in a case of performing a third simulation that simulates a situation in which at least a part of the human workers is replaced with a second robot with respect to the first simulation, the control unit selects the second robot to be replaced with at least a part of the human workers in the third simulation from among a plurality of types of robots on the basis of the first model data corresponding to the individual human worker

According to the twelfth aspect, in a case in which the third simulation that simulates a situation in which at least a part of the human workers who works together with the first robot is replaced with the second robot is performed, the second robot to be replaced with the part of the human workers can be appropriately selected.

According to a thirteenth aspect, in the eighth aspect or the ninth aspect, in a case in which a third simulation simulating a situation in which at least a part of the human workers is replaced with a second robot in the first simulation is performed, the generation unit generates third model data obtained by modeling the work by the second robot, and the control unit performs the third simulation also using the third model data generated by the generation unit.

According to the thirteenth aspect, in a case in which the third simulation that simulates a situation in which at least a part of the human workers who works together with the first robot is replaced with the second robot is performed, the accuracy of the third simulation can be further improved by also using the third model data that models the second robot.

According to a fourteenth aspect, in the eighth aspect or the ninth aspect, in a case in which a third simulation that simulates a situation in which at least a part of the human workers is replaced with a second robot with respect to the first simulation is performed, the control unit sets the work speed of the second robot in the third simulation on the basis of the work speed of the individual human worker included in the first model data corresponding to the individual human worker.

According to the fourteenth aspect, the work speed of the second robot in the third simulation simulating the situation in which at least a part of the human workers who works together with the first robot is replaced with the second robot can be appropriately set on the basis of the work speed of the human worker who is replaced with the second robot.

A program according to a fifteenth aspect causes a computer to execute processing including: acquiring sensor information detected by a plurality of sensors having a work space in which a human worker and a first robot each perform work accompanied by movement as a detection target; generating first model data obtained by modeling the work by the human worker and second model data obtained by modeling the work by the first robot on the basis of the acquired sensor information; and performing a first simulation simulating a situation in which the human worker and the first robot each perform the work in the work space on the basis of the generated first model data and second model data.

According to the fifteenth aspect, it is possible to improve the accuracy of the first simulation that simulates a situation in which the human worker and the first robot perform work in a mixed manner.

Note that the above summary of the disclosure does not enumerate all the necessary features of the disclosure. A sub-combination of these feature groups may also be disclosed.

### BRIEF DESCRIPTION OF DRAWINGS

FIG. 1 is a plan view of a floor of a warehouse on which picking work according to a first embodiment is performed.

FIG. 2 is a block diagram illustrating an example of a functional configuration of an information processing apparatus according to the first embodiment.

FIG. 3 is a flowchart illustrating an example of a processing routine executed by the information processing apparatus according to the first embodiment.

FIG. 4 is a block diagram schematically illustrating an example of a hardware configuration of a computer that functions as an information processing apparatus according to each embodiment.

FIG. 5 is a diagram illustrating an example of data regarding specifications of the robot according to each embodiment.

FIG. 6 is a plan view of a floor of a warehouse on which picking work according to a second embodiment is performed.

FIG. 7 is a block diagram illustrating an example of a functional configuration of an information processing apparatus according to the second embodiment.

FIG. 8 is a flowchart illustrating an example of a processing routine executed by the information processing apparatus according to the second embodiment.

### DESCRIPTION OF EMBODIMENTS

Hereinafter, the disclosure will be described through embodiments of the disclosure, but the following embodiments do not limit the disclosure according to the claims. In addition, not all combinations of features described in the embodiments are essential to the disclosed solutions.

### First Embodiment

In a case in which work by a human worker in a work space such as a warehouse is robotized to aim at significant improvement in productivity, it is difficult to realize the robotization simply by replacing the human worker with the robot and setting a work speed such as a movement speed and an operating speed of the robot. Therefore, a simulation system according to the present embodiment performs a complete simulation of all operations such as layout, each function, the number of persons, an automated machine, a belt conveyor, each speed, off-loading, storing, picking, sorting, packing, and on-loading of a warehouse to be robotized in a three-dimensional virtual space such as a metaverse on the basis of sensor information detected by a plurality of sensors installed in the warehouse in which a human worker performs work accompanied by movement as a detection target. As a result, it is possible to reproduce the warehouse work by the digital twin and perform a transition simulation of the robotization of the warehouse work.

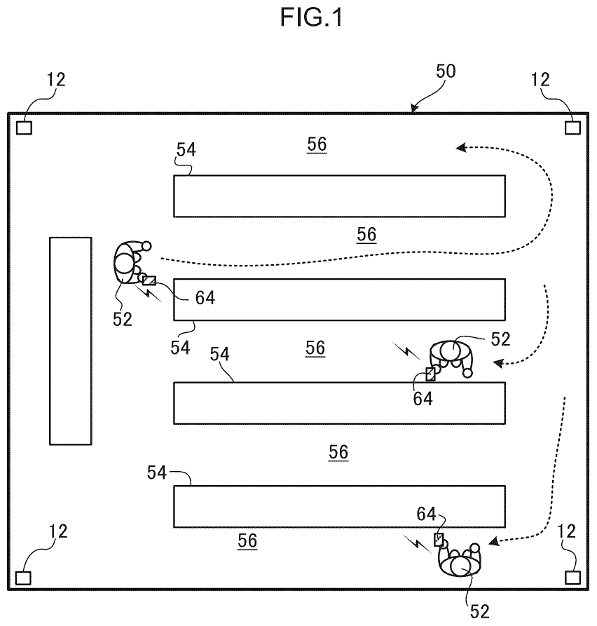

FIG. 1 is a plan view of a floor 50 of a warehouse as an example of an area where a human worker 52 moves and executes work. The work performed by the human worker 52 is, for example, picking work. The picking work according to the present embodiment is work of collecting (picking up) necessary items. The human worker 52, who is a picking staff member, has a role indispensable for shipping an item in the warehouse, and is thus disposed in a warehouse of any kind. The item picked up by the human worker 52 is an example of a work target object by the human worker 52.

For example, the main work is to collect designated items on the basis of a list or an order instructed in advance, and deliver the collected items to an inspection person or a packing person. As the warehouse scale is larger, the types and the number of stored items are enormous, and thus a large number of human workers 52 move in the floor 50.

As illustrated in FIG. 1, a plurality of shelves 54 are installed on the floor 50, and a space between the shelves 54 and a space between the wall of the floor 50 and the shelf 54 is a moving passage 56 of the human worker 52. The human worker 52 receives information of a list or an order from a management control device managing the floor 50 by a mobile terminal 64, moves on the moving passage 56 according to the received information, and picks up a target item. An object other than the shelf 54 such as a belt conveyor may be installed on the floor 50.

A plurality of sensors 12 are installed in the floor 50. The sensors 12 are installed at a plurality of positions so that there is no blind spot on the floor 50. The sensor 12 detects the human worker 52. In addition, the sensor 12 detects not only the human worker 52 but also various types of information for reproducing the work in the warehouse such as the size, shape, number, and type of the item and the shelf 54 in the three-dimensional virtual space. As the sensor 12, a highest-performance camera, a solid-state LiDAR, a multi-color laser coaxial displacement meter, or various other sensor groups can be adopted. In addition, examples of the sensor 12 include a vibratory meter, a thermo camera, a hardness meter, radar, LiDAR, a high-pixel, telephoto, ultra-wide angle, 360 degrees, high-performance camera, vision recognition, fine sound, ultrasonic wave, vibration, infrared ray, ultraviolet ray, electromagnetic wave, temperature, humidity, spot AI weather forecast, high-accuracy multi-channel GPS, low-altitude satellite information, long tail incident AI data, and the like.

In addition to the above-described information, the sensor 12 may detect an image, a distance, vibration, heat, smell, color, sound, ultrasonic wave, ultraviolet ray, infrared ray, or the like. In addition, examples of the information detected by the sensor 12 include the movement of the center of gravity of the human worker 52, the detection of the material of the floor on which the human worker 52 moves, the detection of the outside air temperature, the detection of the outside air humidity, the detection of the vertical and lateral oblique inclination angle of the floor, and the detection of the moisture amount.

The sensor 12 performs these detections, for example, every nanosecond. Private areas such as break rooms and restrooms are excluded from monitoring by the sensor 12. In addition, in order to protect the privacy of each human worker 52, the face, the body shape, the ID, and the like of the human worker 52 are completely masked.

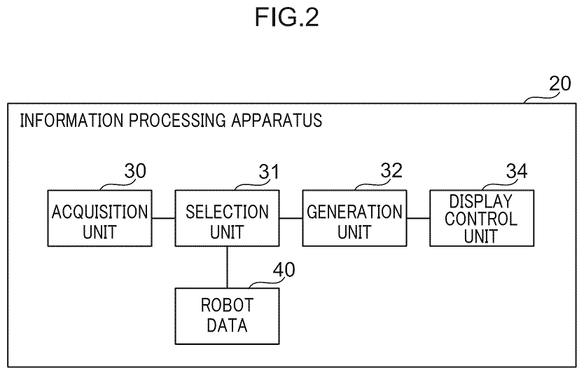

FIG. 2 is a block diagram illustrating an example of a functional configuration of the information processing apparatus 20 included in the simulation system according to the present embodiment. The information processing apparatus 20 includes an acquisition unit 30, a selection unit 31, a generation unit 32, and a display control unit 34. A storage device included in the information processing apparatus 20 stores robot data 40.

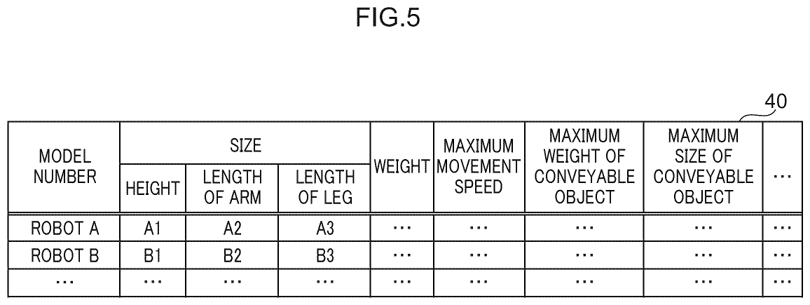

The robot data 40 includes data related to specifications of a plurality of types of robots having different specifications. In the present embodiment, the robot data 40 includes data related to specifications of humanoid robots. As illustrated in FIG. 5 as an example, the robot data 40 includes, for each model number of the robot, a size of the robot, a weight of the robot, a maximum movement speed of the robot, a maximum weight of an item that can be carried by the robot, and a maximum size of an item that can be carried by the robot as specifications of the robot. The model number of the robot is an example of identification information for identifying the robot. In addition, the size of the robot includes the height, the length of the arm, and the length of the leg of the robot. Note that the specification of the robot may include the number of joints of the arm, the number of joints of the leg, and the like.

The acquisition unit 30 acquires sensor information detected in real time by the plurality of sensors 12 installed in the floor 50.

The selection unit 31 derives work information related to the work of the human worker 52 on the basis of the sensor information acquired by the acquisition unit 30. In the present embodiment, the selection unit 31 derives the physique of the human worker 52, the weight of the work target item, the number of the work target items, the movement distance of the human worker 52, and the movement speed of the human worker 52 as the work information. These pieces of work information are derived, for example, by analyzing an image of the floor 50 included in the sensor information captured by the digital camera. In addition, these pieces of work information are derived using, for example, a distance from the sensor 12 to the human worker 52 or the work target item obtained by radar or LiDAR.

In addition, the selection unit 31 selects a robot for replacing the work of the human worker 52 from among a plurality of types of robots having different specifications. Specifically, the selection unit 31 selects a robot from among a plurality of types of robots included in the robot data 40 on the basis of the derived work information. For example, the selection unit 31 selects a robot capable of executing the work indicated by the derived work information from among a plurality of types of robots included in the robot data 40. The selection unit 31 derives the work information for each human worker 52 on the basis of the sensor information, and selects the robot on the basis of the work information. The robot capable of performing the work is, for example, a robot in which the maximum weight of the item that can be carried is equal to or more than the weight of the work target item carried by the work. In addition, the robot capable of executing the work is, for example, a robot in which the maximum movement speed when carrying the work target item is equal to or higher than the movement speed of the human worker 52.

In a case in which there are a plurality of types of robots capable of executing work, the selection unit 31 may select a robot having a size closest to the physique of the human worker 52. Furthermore, in a case in which there are a plurality of types of robots capable of executing work, the selection unit 31 may select a robot having a size closest to the average physique of all the human workers 52. Furthermore, for example, the selection unit 31 may select a robot by inputting the derived work information to a trained model that receives the work information as an input and outputs a model number of the robot optimal for the work indicated by the work information. The trained model in this case may be obtained in advance by machine learning using training data.

The robot selection processing by the selection unit 31 described above may not be executed every time the acquisition unit 30 acquires the sensor information. In this case, the robot selection processing by the selection unit 31 is executed every preset time interval such as 10 minutes on the basis of the sensor information acquired during the time interval.

The generation unit 32 generates model data obtained by modeling a robot for replacing the work of the human worker 52 other than a manager on the basis of the sensor information acquired by the acquisition unit 30. The model data includes robot models and various specifications. Specifically, the generation unit 32 refers to the robot data 40 and generates model data obtained by modeling the robot selected by the selection unit 31.

Furthermore, when generating the model data of the robot, the generation unit 32 may average the body shape of the human worker 52 and reproduce the robot corresponding to the human worker 52 with a simple serial number.

In addition, the generation unit 32 also generates model data obtained by modeling an object other than the human worker 52 such as the shelf 54 and the moving passage 56 on the basis of the sensor information acquired by the acquisition unit 30.

The generation unit 32 generates and updates the model data in real time each time the acquisition unit 30 acquires the sensor information.

The display control unit 34 performs control to display the robot and various objects on a display device such as a liquid crystal display after arranging the robot and various objects in a three-dimensional virtual space on the basis of the model data generated by the generation unit 32. In a case in which the model data is updated by the generation unit 32, the display control unit 34 updates the display of the robot and various objects in the three-dimensional virtual space. As a result, the work of the floor 50 of the warehouse is reproduced in the three-dimensional virtual space.

The information processing apparatus 20 may estimate the number of received items and the number of shipped items at the peak time, and cause an avatar representing the robot in the three-dimensional virtual space to execute the work at the same speed as the work speed of the human worker 52 assuming the estimated situation at the peak time.

In addition, the information processing apparatus 20 may repeatedly perform a simulation such as changing the layout in the warehouse, the specification of the robot, the number of robots, and the like in the three-dimensional virtual space until the work speed at which the number of received items and the number of shipped items n times can be achieved is completely realized. The magnification n in this case may be specified by the user.

As described above, it is possible to find measures such as a layout change in the warehouse and a change in the number of robots by repeatedly simulating reproduction of operations in the warehouse and execution of operations at various work speeds in the three-dimensional virtual space. This simulation enables output at a receiving speed and a shipping speed that are about 3 to 20 times the current speed.

In addition, the user can input a success rate of work such as pickup performed by the prototype robot to the information processing apparatus 20, and perform monitoring at the time of work failure and a test of rescue work by a human.

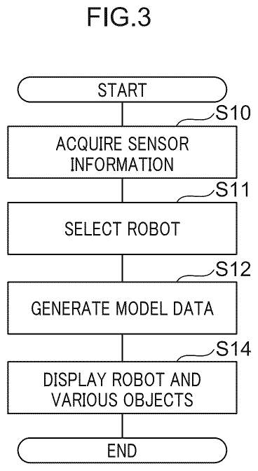

The information processing apparatus 20 repeatedly executes the flowchart illustrated in FIG. 3.

In step S10, the acquisition unit 30 acquires sensor information detected in real time by the plurality of sensors 12 installed in the floor 50.

In step S11, as described above, the selection unit 31 derives the work information related to the work of the human worker 52 on the basis of the sensor information acquired in step S10, and selects the robot on the basis of the derived work information.

In step S12, as described above, the generation unit 32 generates model data in which a robot for replacing the work of the human worker 52 and an object other than the human worker 52 are modeled on the basis of the sensor information acquired in step S10 and the robot selected in step S11.

In step S14, the display control unit 34 performs control to display the robot and various objects on a display device such as a liquid crystal display after arranging the robot and various objects in a three-dimensional virtual space on the basis of the model data generated in step S12. When the process of step S14 ends, the process of the flowchart ends.

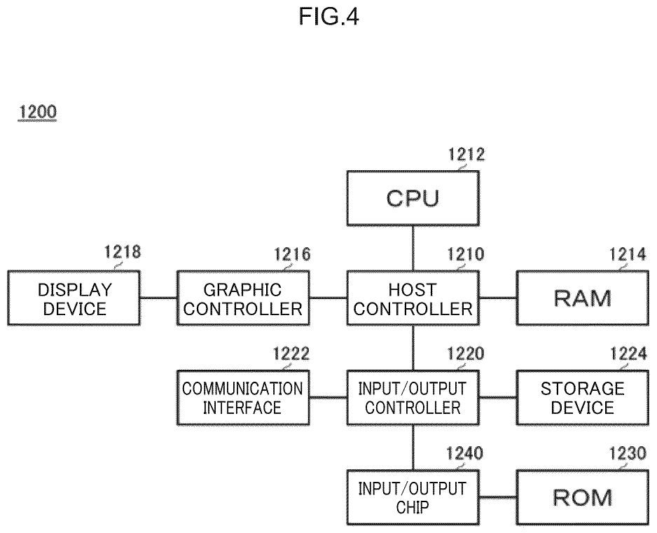

FIG. 4 schematically illustrates an example of a hardware configuration of a computer 1200 that functions as the information processing apparatus 20. The program installed in the computer 1200 can cause the computer 1200 to function as one or more “units” of the apparatus according to the present embodiment, or cause the computer 1200 to execute an operation associated with the apparatus according to the present embodiment or one or more “units” thereof, and/or cause the computer 1200 to execute a process according to the present embodiment or a stage of the process. Such programs may be executed by a CPU 1212 to cause the computer 1200 to perform certain operations associated with some or all of the blocks in the flowcharts and block diagrams described herein.

The computer 1200 according to the present embodiment includes a CPU 1212, a RAM 1214, and a graphic controller 1216, which are mutually connected by a host controller 1210. The computer 1200 also includes input/output units such as a communication interface 1222, a storage device 1224, a DVD drive, and an IC card drive, which are connected to the host controller 1210 via an input/output controller 1220. The DVD drive may be a DVD-ROM drive, a DVD-RAM drive, or the like. The storage device 1224 may be a hard disk drive, a solid state drive, or the like. The computer 1200 also includes a ROM 1230 and legacy input/output units such as a keyboard, which are connected to the input/output controller 1220 via an input/output chip 1240.

The CPU 1212 operates according to programs stored in the ROM 1230 and the RAM 1214, thereby controlling each unit. The graphic controller 1216 obtains image data generated by the CPU 1212 in a frame buffer or the like provided in the RAM 1214 or the graphic controller itself, and causes the image data to be displayed on the display device 1218.

The communication interface 1222 communicates with other electronic devices via a network.

The storage device 1224 stores programs and data used by the CPU 1212 in the computer 1200. The DVD drive reads a program or data from a DVD-ROM or the like and provides the program or data to the storage device 1224. The IC card drive reads the program and data from the IC card and/or writes the program and data to the IC card.

The ROM 1230 stores therein a boot program executed by the computer 1200 at the time of activation and/or a program depending on hardware of the computer 1200. The input/output chip 1240 may also connect various input/output units to the input/output controller 1220 via a USB port, a parallel port, a serial port, a keyboard port, a mouse port, or the like.

The program is provided by a computer-readable storage medium such as a DVD-ROM or an IC card. The program is read from a computer-readable storage medium, installed in the storage device 1224, the RAM 1214, or the ROM 1230, which is also an example of a computer-readable storage medium, and executed by the CPU 1212. The information processing described in these programs is read by the computer 1200 and provides cooperation between the programs and the various types of hardware resources described above. The apparatus or method may be configured by implementing operation or processing of information according to use of the computer 1200.

For example, in a case in which communication is performed between the computer 1200 and an external device, the CPU 1212 may execute a communication program loaded in the RAM 1214 and instruct the communication interface 1222 to perform communication processing on the basis of processing described in the communication program. Under the control of the CPU 1212, the communication interface 1222 reads transmission data stored in a transmission buffer area provided in a recording medium such as the RAM 1214, the storage device 1224, the DVD-ROM, or the IC card, transmits the read transmission data to the network, or writes reception data received from the network to a reception buffer area or the like provided on the recording medium.

In addition, the CPU 1212 may cause the RAM 1214 to read all or a necessary portion of a file or database stored in an external recording medium such as the storage device 1224, a DVD drive (DVD-ROM), an IC card, or the like, and may execute various types of processing on data on the RAM 1214. Next, the CPU 1212 may write back the processed data to the external recording medium.

Various types of information such as various types of programs, data, tables, and databases may be stored in a recording medium and subjected to information processing. The CPU 1212 may execute various types of processing on the data read from the RAM 1214, including various types of operations, information processing, condition determination, conditional branching, unconditional branching, information retrieval/replacement, and the like, which are described throughout the disclosure and specified by a command sequence of a program, and writes back the results to the RAM 1214. In addition, the CPU 1212 may search for information in a file, a database, or the like in the recording medium. For example, in a case in which a plurality of entries each having an attribute value of a first attribute associated with an attribute value of a second attribute is stored in the recording medium, the CPU 1212 may search for an entry in which the attribute value of the first attribute matches the specified condition from the plurality of entries, read the attribute value of the second attribute stored in the entry, and thereby acquire the attribute value of the second attribute associated with the first attribute satisfying the predetermined condition.

The program or software module described above may be stored in a computer readable storage medium on the computer 1200 or in the vicinity of the computer 1200. Furthermore, a recording medium such as a hard disk or a RAM provided in a server system connected to a dedicated communication network or the Internet can be used as a computer-readable storage medium, thereby providing a program to the computer 1200 via the network.

The blocks in the flowcharts and block diagrams in this embodiment may represent stages of a process in which an operation is performed or “units” of a device that are responsible for performing the operation. Certain stages and “units” may be implemented by dedicated circuit, programmable circuit provided with computer-readable instructions stored on a computer-readable storage medium, and/or a processor provided with computer-readable instructions stored on a computer-readable storage medium. The dedicated circuits may include digital and/or analog hardware circuits, and may include integrated circuits (ICs) and/or discrete circuits. The programmable circuit may include reconfigurable hardware circuit including, for example, logical conjunction, logical disjunction, exclusive disjunction, NAND, NOR, and other logical operations, flip-flops, registers, and memory elements, such as field programmable gate arrays (FPGA) and programmable logic arrays (PLA).

A computer-readable storage medium may include any tangible device capable of storing instructions for execution by a suitable device, such that a computer-readable storage medium having instructions stored therein includes a product including instructions that may be executed to create means for performing the operations specified in the flowcharts or block diagrams. Examples of the computer-readable storage medium may include an electronic storage medium, a magnetic storage medium, an optical storage medium, an electromagnetic storage medium, a semiconductor storage medium, and the like. More specific examples of the computer readable storage medium may include a floppy disk (registered trademark), a diskette, a hard disk, a random access memory (RAM), a read-only memory (ROM), an erasable programmable read-only memory (EPROM or flash memory), an electrically erasable programmable read-only memory (EEPROM), a static random access memory (SRAM), a compact disc read-only memory (CD-ROM), a digital versatile disk (DVD), a Blu-Ray disk (registered trademark), a memory stick, an integrated circuit card, and the like.

The computer-readable instructions may include either source code or object code written in any combination of one or more programming languages, including assembler instructions, instruction-set-architecture (ISA) instructions, machine instructions, machine-dependent instructions, microcode, firmware instructions, state-setting data, or an object oriented programming language such as Smalltalk (registered trademark), JAVA (registered trademark), C++, or the like, and conventional procedural programming languages, such as the “C” programming language or similar programming languages.

The computer readable instructions may be provided for a processor of general purpose computer, special purpose computer, or other programmable data processing apparatus, or a programmable circuit, either locally or over a wide area network (WAN), such as a local area network (LAN), the Internet, or the like, to cause the processor of general purpose computer, special purpose computer, or other programmable data processing apparatus, or the programmable circuit to execute the computer readable instructions to generate means for performing the operations specified in the flowcharts or block diagrams. Examples of the processor include a computer processor, a processing unit, a microprocessor, a digital signal processor, a controller, a microcontroller, and the like.

### Second Embodiment

Next, a second embodiment of the disclosure will be described. The same portions as those of the first embodiment are denoted by the same reference numerals, and the description thereof will be omitted.

In a case in which the work by the human worker in the work space such as the warehouse is robotized, it is not realistic to replace all the human workers engaged in the work with the robot at a time because an error with respect to the transition simulation cannot be ignored. For this reason, the above-described robotization is realized by performing a transition simulation in a case in which some human workers are replaced with robots, and repeating the actual replacement of some human workers with robots a plurality of times on the basis of the result. Therefore, in the process of the robotization, a situation occurs in which the human worker and the robot work in a mixed manner in the work space.

Therefore, in the present embodiment, with respect to a situation in which the human worker and the robot work in a mixed manner in the work space, first, a first simulation simulating a situation in which the human worker and the first robot each perform work accompanied by movement in the work space is performed, which will be described below in detail. In addition, in a case in which the work speed of the entire floor 50 does not reach the target from the result of the first simulation, for example, a second simulation that simulates a situation in which the work speed of a first robot is changed with respect to the first simulation, or a third simulation that simulates a situation in which at least a part of the human workers is replaced with a second robot with respect to the first simulation is performed.

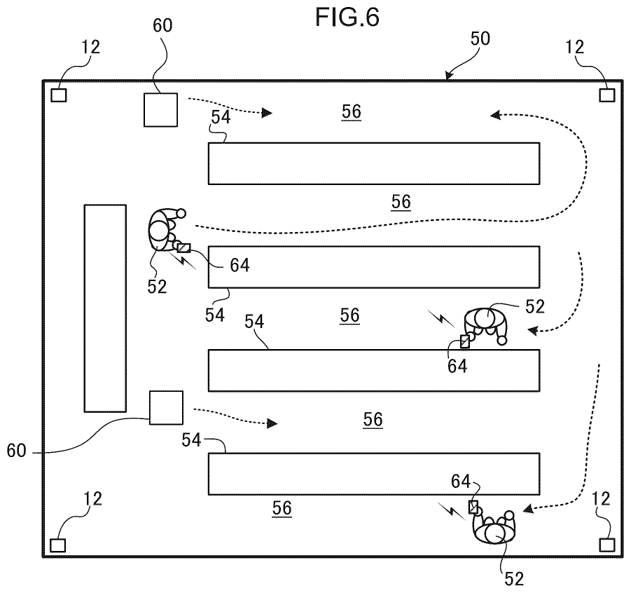

FIG. 6 is a plan view of the floor 50 of a warehouse as an example of a work space in which the human worker 52 and the robot 60 perform work accompanied by movement. Note that, at the timing before the robotization is performed, for example, only the human worker 52 exists on the floor 50, and at the timing after the completion of the robotization, for example, only the robot 60 exists on the floor 50. However, FIG. 6 illustrates a situation at the timing during the robotization, that is, a situation where the human worker 52 and the robot 60 are mixed on the floor 50. In FIG. 6, the robot 60 disposed on the floor 50 is an example of the first robot in the disclosure. Note that, in the disclosure, the robot 60 may be a humanoid robot or a non-humanoid robot as long as the robot can perform work accompanied by movement, which is similar to the human worker 52.

The work performed by the human worker 52 and the robot 60 is, for example, picking work similar to that of the first embodiment.

In the second embodiment, in addition to the human worker 52, the robot 60 also moves in the floor 50. In addition, the sensor 12 also detects the robot 60 in addition to the human worker 52. Note that the sensor 12 is not limited to being installed in the floor 50, and may be installed or attached to at least one of the human worker 52 and the robot 60 existing in the floor 50.

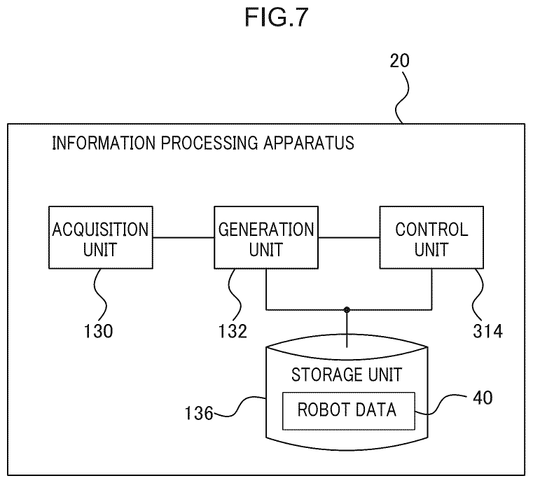

FIG. 7 is a block diagram illustrating an example of a functional configuration of the information processing apparatus 20 included in the simulation system according to the present embodiment. The information processing apparatus 20 includes an acquisition unit 130, a generation unit 132, a control unit 134, and a storage unit 136. In the present embodiment, the robot 60 (an example of the second robot 60 in the disclosure) that replaces the human worker 52 that performs work on the floor 50 can be selected from a plurality of types of robots 60 having different specifications, and the storage unit 136 stores the robot data 40.

The robot data 40 is data similar to that of the first embodiment, and includes data related to specifications of the plurality of types of robots 60. As illustrated in FIG. 5 as an example, the robot data 40 includes, for each model number of the robot 60, a size of the robot 60, a weight of the robot 60, a maximum movement speed of the robot 60, a maximum weight of an item that can be carried by the robot 60, and a maximum size of an item that can be carried by the robot 60 as specifications of the robot 60. The model number of the robot 60 is an example of identification information for identifying the robot 60. In addition, the size of the robot 60 includes the height, the length of the arm, and the length of the leg of the robot 60. Note that the specification of the robot 60 may include the number of joints of the arm, the number of joints of the leg, and the like.

Note that the disclosure also includes an aspect in which the robot 60 (second robot 60) replacing the human worker 52 that performs work on the floor 50 is limited to a single type of robot 60 with constant specifications. In this aspect, (the storage unit 136 storing) the robot data 40 can be omitted, and the process of selecting the robot 60 functioning as the second robot 60 can be omitted.

The acquisition unit 130 acquires sensor information detected in real time by the plurality of sensors 12 installed in the floor 50.

The generation unit 132 generates first model data obtained by modeling the work by the individual human worker 52 corresponding to the individual human worker 52 other than the manager existing in the floor 50 on the basis of the sensor information acquired by the acquisition unit 130. Note that the first model data corresponding to the individual human worker 52 includes at least information on the work speed of the individual human worker 52.

Furthermore, in the present embodiment, the first model data may include work information related to the work of the human worker 52, such as the physique of the human worker 52, the weight of the work target item, the number of work target items, the movement distance of the human worker 52, and the movement speed of the human worker 52, for example. The generation unit 132 can derive the work information from the sensor information acquired by the acquisition unit 130. The work information can be derived, for example, by analyzing an image of the floor 50 included in the sensor information captured by the digital camera. Furthermore, the work information can be derived using, for example, a distance to the human worker 52 or the work target item obtained from the sensor 12 such as radar or LiDAR.

In a case in which the robot 60 (first robot 60) is present on the floor 50, the generation unit 132 also generates second model data obtained by modeling the work by the first robot 60 present on the floor 50 on the basis of the sensor information acquired by the acquisition unit 130. The second model data may include the type and various specifications of the first robot 60. Furthermore, when the second model data is generated, the body shape of the human worker 52 may be averaged, and the robot 60 may be reproduced with a simple serial number.

Further, in a case in which the third simulation is performed, the generation unit 132 also generates third model data obtained by modeling the second robot 60 (the robot 60 selected by the control unit 134 to be described below) to replace the human worker 52 that performs work on the floor 50 on the basis of the robot data 40 stored in the storage unit 136. Note that, when generating the third model data, the generation unit 132 may average the body shape of the human worker 52 and reproduce the robot corresponding to the human worker 52 with a simple serial number.

In addition, the generation unit 132 also generates model data obtained by modeling objects other than the human worker 52 and the robot 60 such as the shelf 54 and the moving passage 56 on the basis of the sensor information acquired by the acquisition unit 130. The generation unit 132 generates and updates each piece of the model data in real time each time the acquisition unit 130 acquires the sensor information.

In a case of performing any one of the first to third simulations, the control unit 134 generates a three-dimensional virtual space simulating the shelf 54, the moving passage 56, and the like on the floor 50 based on each piece of model data generated by the generation unit 132. In addition, in a case in which the first simulation or the second simulation is performed, the control unit 134 arranges the object corresponding to the human worker 52 in the three-dimensional virtual space on the basis of the first model data, and arranges the object corresponding to the first robot 60 in the three-dimensional virtual space on the basis of the second model data. In a case in which the second simulation is performed, the control unit 134 changes and sets the work speed of the first robot 60 on the basis of the work speed of the human worker 52 included in the first model data or the like (updates the second model data) before arranging the object corresponding to the first robot 60 in the three-dimensional virtual space.

Then, the control unit 134 performs a simulation for causing each object corresponding to the human worker 52 or the first robot 60 arranged in the three-dimensional virtual space to perform work accompanied by movement in the three-dimensional virtual space on the basis of each piece of model data including the first model data and the second model data. As a result, the first simulation that accurately simulates a situation in which the human worker 52 and the first robot 60 work in a mixed manner or the second simulation that accurately simulates a situation in which the work speed of the first robot 60 is changed from that of the first simulation is realized.

In the present embodiment, in a case in which the third simulation of replacing at least a part of the human workers 52 that performs work on the floor 50 with the second robot 60 is performed, the control unit 134 selects the human worker 52 (a replacement target human worker 52) to be replaced with the second robot 60 on the basis of the first model data. The replacement target human worker 52 can be selected, for example, on the basis of the work speed of the individual human worker 52 included in the first model data corresponding to the individual human worker 52, and as an example, a predetermined number of the replacement target human worker 52 can be selected in ascending order of the work speed. As a result, the replacement target human worker 52 can be appropriately selected on the basis of the work speed of the human worker 52 or the like.

In addition, in a case in which the third simulation is performed, the control unit 134 selects the second robot 60 that replaces the replacement target human worker 52 from the plurality of types of robots 60 having different specifications. Specifically, the control unit 134 selects the second robot 60 on the basis of the work information included in the first model data corresponding to the replacement target human worker 52 from the plurality of types of robots 60 of which specifications and the like are set in the robot data 40. For example, the control unit 134 selects the second robot 60 capable of executing the work indicated by the work information from among the plurality of types of robots 60. An example of the second robot 60 capable of performing the work is a robot 60 in which the maximum weight of the item that can be carried is equal to or more than the weight of the work target item carried by the work. In addition, another example of the second robot 60 capable of executing the work is a robot 60 in which the maximum movement speed at the time of transporting the work target item is equal to or higher than the movement speed of the human worker 52.

In a case in which there is a plurality of types of the second robots 60 capable of executing the work, the control unit 134 may select the robot 60 having a size closest to the physique of the replacement target human worker 52. Furthermore, in a case in which there are a plurality of types of the second robots 60 capable of executing the work, the control unit 134 may select the robot 60 having a size closest to the average physique of the human worker 52. For example, the control unit 134 may select the second robot 60 by inputting the work information to a trained model that receives the work information and outputs the model number of the robot 60 optimal for the work indicated by the work information. The trained model in this case may be obtained in advance by machine learning using training data.

The selection of the second robot 60 by the control unit 134 may not be executed every time the acquisition unit 130 acquires the sensor information. In this case, the selection of the second robot 60 by the control unit 134 may be performed every preset time interval such as 10 minutes on the basis of the sensor information acquired during the time interval.

In addition, in a case in which the third simulation is performed, the control unit 134 arranges the object corresponding to the human worker 52 that is not the replacement target in the three-dimensional virtual space on the basis of the first model data corresponding to a part of the human workers 52 (the human worker 52 that is not the replacement target) that is not replaced with the second robot in the current simulation among the human workers 52 working on the floor 50. In addition, the control unit 134 arranges the object corresponding to the first robot 60 in the three-dimensional virtual space on the basis of the second model data. Further, the control unit 134 arranges the object corresponding to the second robot 60 that replaces the replacement target human worker 52 in the current simulation in the three-dimensional virtual space on the basis of the third model data.

Note that, at this time, the control unit 134 may set the work speed of the second robot 60 on the basis of the work speed of the replacement target human worker 52 included in the first model data corresponding to the replacement target human worker 52. In this case, the work speed of the second robot 60 in the simulation can be appropriately set according to the work speed of the replacement target human worker 52.

Then, the control unit 134 performs a simulation for causing each object corresponding to any one of the human worker 52, the first robot 60, and the second robot 60 arranged in the three-dimensional virtual space to perform work accompanied by movement in the three-dimensional virtual space on the basis of each piece of model data including the first model data to the third model data. As a result, the third simulation that accurately estimates the situation in which the replacement target human worker 52 among the human workers 52 that work in a mixed manner with the first robot 60 is replaced with the second robot 60 is realized.

Note that the control unit 134 may appropriately display the progress, the result, and the like of the simulation on a display device such as a liquid crystal display. Furthermore, in a case in which each piece of model data is updated by the generation unit 132, the control unit 134 may update the arrangement and the like of individual objects corresponding to any one of the human worker 52, the first robot 60, and the second robot 60 in the three-dimensional virtual space. As a result, the work of the floor 50 of the warehouse is reproduced in the three-dimensional virtual space. Furthermore, the control unit 134 may estimate the number of received items and the number of shipped items at the peak time of the warehouse, and estimate the estimated state at the peak time by simulation.

Furthermore, the control unit 134 (the information processing apparatus 20) may repeatedly perform a simulation such as changing the layout in the warehouse, the specifications of the robot 60, the number of robots 60, and the like in the three-dimensional virtual space until the work speed at which the number of received items and the number of shipped items that are n times as large can be achieved is completely realized. The magnification n in this case may be specified by the user, or the double speed of the operation is set according to the ability of the human worker.

As described above, it is possible to find measures such as a layout change in the warehouse and a change in the number of robots 60 by repeatedly simulating reproduction of operations in the warehouse and execution of operations at various work speeds in the three-dimensional virtual space. This simulation enables output at a receiving speed and a shipping speed that are about 3 to 20 times the current speed.

In addition, the user can input a success rate of work such as pickup performed by the prototype robot 60 to the information processing apparatus 20, and perform monitoring at the time of work failure and a test of rescue work by a human.

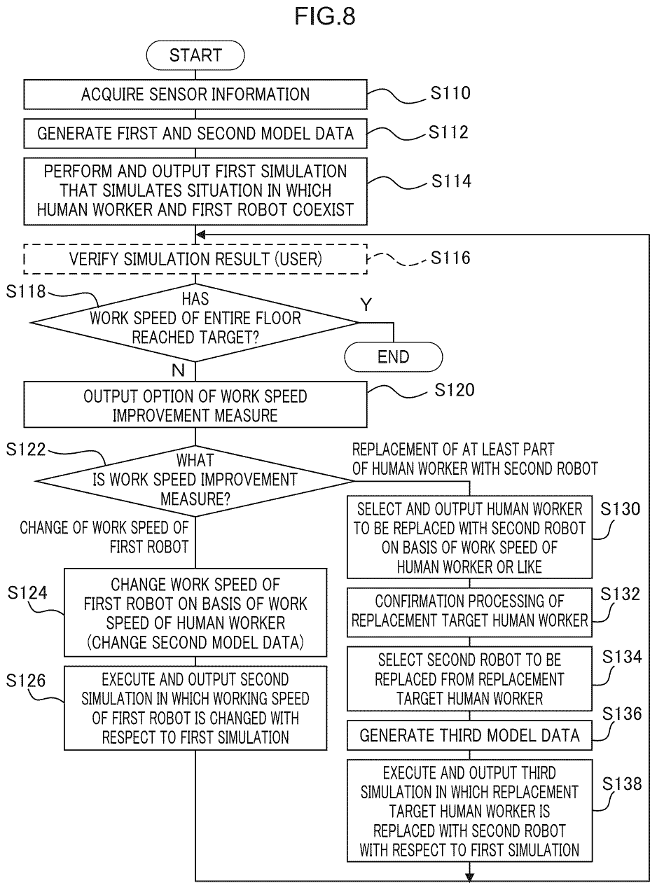

The information processing apparatus 20 repeatedly executes the processing illustrated in the flowchart in FIG. 8.

In step S110, the acquisition unit 130 acquires sensor information detected in real time by the plurality of sensors 12 whose detection target is the inside of the floor 50.

In step S112, as described above, the generation unit 132 generates the first model data obtained by modeling the work by the human worker 52 existing in the floor 50 and the second model data obtained by modeling the work by the first robot 60 existing in the floor 50 on the basis of the sensor information acquired in step S110. Note that the processing of steps S110 and S112 is repeatedly executed in parallel, for example, at nanosecond intervals, even while the processing of the next step S114 and subsequent steps is performed.

In step S114, as described above, the control unit 134 performs the first simulation that simulates the situation in which the human worker 52 and the first robot 60 coexist, and outputs the execution result of the first simulation to the display device or the like.

When the execution result of the first simulation is output to the display device or the like, the user refers to the execution result of the first simulation, and performs work of verifying the simulation result, for example, work of verifying whether or not the work speed of the entire floor 50 in the first simulation is appropriate (step S116).

In step S118, the control unit 134 determines whether the work speed of the entire floor 50 has reached the target on the basis of the result of the verification work input by the user via the input device, and the like. In a case in which the determination in step S118 is affirmative, the execution of the processing illustrated in the flowchart of FIG. 8 ends.

In addition, in a case in which the determination in step S118 is negative, the processing proceeds to step S120, and the control unit 134 outputs information recommending execution of the second simulation and the third simulation to a display device or the like as an option of the work speed improvement measure, thereby performing processing of suggesting to the user. In the next step S122, the control unit 134 determines a work speed improvement measure selected by the user, and branches according to the determination result.

In a case in which execution of the second simulation is selected by the user as a work speed improvement measure, the process proceeds from step S122 to step S124. In step S124, the control unit 134 changes the second model data so that the work speed of the first robot 60 is changed on the basis of the work speed of the human worker 52 and the like as described above. Then, in the next step S126, the control unit 134 executes the second simulation in which the working speed of the first robot 60 is changed with respect to the first simulation, and outputs the result of the second simulation to the display device or the like. When the process of step S126 ends, the process returns to step S116.

In a case in which execution of the third simulation is selected by the user as a work speed improvement measure, the process proceeds from step S122 to step S130. In step S130, as described above, the control unit 134 selects the replacement target human worker 52 with the second robot 60 in the current simulation on the basis of the first model data corresponding to the individual human worker 52.

In the next step S132, the control unit 134 outputs the replacement target human worker 52 selected in step S130 to the display device or the like, and performs confirmation processing of requesting approval of the user for the number of replacement target human worker 52 or the like.

In step S134, as described above, the control unit 134 selects the second robot 60 to be replaced from the replacement target human worker 52 on the basis of the first model data corresponding to the replacement target human worker 52.

In step S136, as described above, the generation unit 132 generates the third model data obtained by modeling the work by the second robot 60 to be replaced from the replacement target human worker 52 in the current simulation.

In step S138, on the basis of the third model data generated in step S136 in addition to the first model data and the second model data generated in step S112, the control unit 134 executes the third simulation after arranging the object corresponding to the human worker 52 that is not the replacement target and any one of the first robot 60 and the second robot in the three-dimensional virtual space. When the process of step S138 ends, the process returns to step S116.

Although the disclosure has been described with reference to the exemplary embodiments, the technical scope of the disclosure is not limited to the scope described in the exemplary embodiments. It is apparent to those skilled in the art that various modifications or improvements can be made to the above embodiments. It is apparent from the description of the claims that a mode to which such a change or improvement is added can also be included in the technical scope of the disclosure.

It should be noted that the order of execution of each processing such as operations, procedures, steps, and stages in the devices, systems, programs, and methods illustrated in the claims, the specification, and the drawings can be realized in any order unless “before”, “prior to”, or the like is explicitly stated, and unless the output of the previous processing is used in the later processing. Even if the operation flow in the claims, the specification, and the drawings is described using “First,”, “Next,”, and the like for convenience, it does not mean that it is essential to perform in this order.

The disclosure of Japanese Patent Application No. 2022-169079 filed on Oct. 21, 2022, the disclosure of Japanese Patent Application No. 2022-179649 filed on Nov. 9, 2022, and the disclosure of Japanese Patent Application No. 2022-203354 filed on Dec. 20, 2022 are incorporated herein by reference in their entirety.

1. A simulation system comprising:
a processor configured to
acquire sensor information detected by a plurality of sensors installed in an area in which a human worker moves and performs work;
generate model data obtained by modeling a robot for replacing work of the human worker on the basis of the sensor information; and
perform control to display the robot on the basis of the model data.

2. The simulation system according to claim 1, wherein
the processor updates the model data on the basis of the sensor information detected in real time.

3. The simulation system according to claim 1, wherein the processor is further configured to
select a robot for replacing the work of the human worker from among a plurality of types of robots having different specifications on the basis of the sensor information, and
generate model data obtained by modeling the robot selected by the processor.

4. The simulation system according to claim 3, wherein
the processor derives work information related to work of the human worker on the basis of the sensor information, and selects a robot on the basis of the derived work information.

5. The simulation system according to claim 4, wherein
the work information includes at least one piece of information of a physique of the human worker, a weight of a work target object, a number of work target objects, a movement distance of the human worker, and a movement speed of the human worker.

6. The simulation system according to claim 3, wherein
the specification includes at least one of a size of the robot, a weight of the robot, a maximum movement speed of the robot, a maximum weight of a conveyable object of the robot, and a maximum size of a conveyable object of the robot.

7. A non-transitory computer-readable storage medium storing a program for causing a computer to function as the simulation system according to claim 1.

8. A simulation system comprising:
a processor configured to
acquire sensor information detected by a plurality of sensors having a work space in which a human worker and a first robot each perform work accompanied by movement as a detection target;
generate first model data obtained by modeling the work by the human worker and second model data obtained by modeling the work by the first robot on the basis of the sensor information; and
perform a first simulation that simulates a situation in which the human worker and the first robot each perform the work in the work space on the basis of the first model data and the second model data.

9. The simulation system according to claim 8, wherein in a case in which a result of the first simulation satisfies a predetermined condition, the processor performs processing of suggesting execution of at least one of a second simulation that simulates a situation in which a work speed of the first robot is changed with respect to the first simulation and a third simulation that simulates a situation in which at least a part of the human workers is replaced with a second robot with respect to the first simulation.

10. The simulation system according to claim 8, wherein in a case of performing a second simulation that simulates a situation in which the work speed of the first robot is changed with respect to the first simulation, the processor sets the work speed of the first robot in the second simulation on the basis of the work speed of the individual human worker included in the first model data corresponding to the individual human worker.

11. The simulation system according to claim 8, wherein in a case of performing a third simulation that simulates a situation in which at least a part of the human workers is replaced with a second robot with respect to the first simulation, the processor selects the human worker to be replaced with the second robot in the third simulation on the basis of the work speed of the individual human worker included in the first model data corresponding to the individual human worker.

12. The simulation system according to claim 8, wherein in a case of performing a third simulation that simulates a situation in which at least a part of the human workers is replaced with a second robot with respect to the first simulation, the processor selects the second robot to be replaced with at least a part of the human workers in the third simulation from among a plurality of types of robots on the basis of the first model data corresponding to the individual human worker.

13. The simulation system according to claim 8, wherein
in a case in which a third simulation that simulates a situation in which at least a part of the human workers is replaced with a second robot with respect to the first simulation is performed,
the processor generates third model data obtained by modeling the work by the second robot, and
the processor performs the third simulation also using the third model data.

14. The simulation system according to claim 8, wherein in a case in which a third simulation that simulates a situation in which at least a part of the human workers is replaced with a second robot with respect to the first simulation is performed, the processor sets the work speed of the second robot in the third simulation on the basis of the work speed of the individual human worker included in the first model data corresponding to the individual human worker.

15. A non-transitory computer-readable storage medium storing a program for causing a computer to execute processing including:
acquiring sensor information detected by a plurality of sensors having a work space in which a human worker and a first robot each perform work accompanied by movement as a detection target;
generating first model data obtained by modeling the work by the human worker and second model data obtained by modeling the work by the first robot on the basis of the acquired sensor information; and
performing a first simulation simulating a situation in which the human worker and the first robot each perform the work in the work space on the basis of the generated first model data and second model data.
